(19) United States
(12) Patent Application Publication
(10) Pub. No.: US 2018/0292211 A1
(43) Pub. Date: Oct. 11, 2018

(54) MEMS Yaw-Rate Sensor

(71) Applicant: EPCOS AG, München (DE)

(72) Inventors: Marcus Besson, Taufkirchen (DE); Bernhard Ostrick, Teltow (DE)

(21) Appl. No.: 15/765,581

(22) PCT Filed: Sep. 27, 2016
(86) PCT No.: PCT/EP2016/073005

§ 371 Date: Apr. 3, 2018

(30) Foreign Application Priority Data
Oct. 7, 2015 (DE) 10 2015 117 094.9

(51) Int. Cl. G01C 19/5747; G01C 19/5712; G01C 19/5769; G01R 33/09

(52) U.S. Cl. CPC G01C 19/5747; G01C 19/5712; B81B 2201/0242; G01R 33/098; G01R 33/093; G01C 19/5769

(57) ABSTRACT

A MEMS yaw-rate sensor is disclosed. In an embodiment, the MEMS yaw-rate sensor includes a first primary mass configured to perform a primary oscillation relative to a main body, a first secondary mass connected to the first primary mass via a first suspension such that a primary movement of the first primary mass excites a primary movement of the first secondary mass and a secondary movement of the first secondary mass relative to the first primary mass is permitted, a first magnetic-field-generating element and a first magnet-sensitive element, one being arranged on the main body and one being arranged on the first primary mass, wherein the first magnet-sensitive element is configured to determine the primary movement of the first primary mass relative to the main body and a second magnetic-field-generating element and a second magnet-sensitive element.

This patent application is a national phase filing under section 371 of PCT/EP2016/073005, filed Sep. 27, 2016, which claims the priority of German patent application 10 2015 117 094.9, filed Oct. 7, 2015, each of which is incorporated herein by reference in its entirety.

### TECHNICAL FIELD

The present invention relates to a microelectromechanical system (MEMS) yaw-rate sensor.

### BACKGROUND

There is a variety of technologies and measurement principles for MEMS-based sensors. In particular, capacitive measurement principles are commonly used, in which a capacitance can be formed, for example, by intermeshing finger structures or buried electrode surfaces. In this case, a deflection of a mass structure can be determined by changes in the capacitance. Capacitive sensors are known, for example, from U.S. Pat. No. 7,694,563 B1 or from European Patent No. EP 0 906 557 B2.

In the case of such sensors it is customary to use buried electrodes for detecting a deflection of a mass structure. The buried electrodes must have a sufficiently large area in order to afford a corresponding sensitivity. The possibility for miniaturizing such a sensor is limited as a result.

Furthermore, parasitic capacitances in the MEMS structures can adversely affect the oscillation behavior and the sensitivity of the sensor.

### SUMMARY OF THE INVENTION

Embodiments of the present invention provide an improved sensor.

In various embodiment a MEMS yaw-rate sensor comprises a main body, a first primary mass, which is configured to perform a primary oscillation relative to the main body, and a first secondary mass, which is connected to the first primary mass via a suspension in such a way that the primary movement of the first primary mass excites a primary movement of the first secondary mass, and a secondary movement of the first secondary mass relative to the first primary mass is permitted. In particular, the MEMS yaw-rate sensor can be configured in such a way that the first secondary mass is excited to perform the first secondary movement by a Coriolis force if the MEMS yaw-rate sensor performs a rotation and a primary movement is transmitted from the first primary mass to the first secondary mass. The first secondary movement can be perpendicular to the first primary movement and perpendicular to the rotation axis of an external rotation to be measured. Preferably, the secondary movement is not fed back to the primary mass and accordingly does not influence the movement thereof. Consequently, no disturbance of the excitation should be induced by the secondary movement. Preventing the secondary movement from being fed back to the primary mass can be achieved by means of corresponding configurations of the springs.

The secondary movement can be an oscillation. The primary movement of the first primary mass and the primary movement of the first secondary mass can likewise be an oscillation.

In various further embodiments, the sensor comprises a first magnetic-field-generating element and a first magnet-sensitive element. One of these elements is arranged on the main body and one of the elements is arranged on the first primary mass, wherein the first magnet-sensitive element is configured for determining the primary movement of the first primary mass relative to the main body. If the first primary mass performs a primary movement relative to the main body, then the first magnetic-field-generating element is moved relative to the first magnet-field-generating element. This results in a change in the field strength and/or the field direction of the field generated by the first magnetic-field-generating element at the location of the first magnet-sensitive element. This change can be measured by the first magnet-sensitive element. Conclusions can be drawn therefrom about the relative position of the two elements with respect to one another and thus about the first primary movement.

In yet further embodiments, the sensor can comprise further magnetic-field-generating elements and further magnet-sensitive elements, each of which is arranged either on the main body or on the first primary mass. These elements, too, can measure a relative position of the first primary mass with respect to the main body and thus the first primary movement in accordance with the principle described above. Ambiguities in the measurement data can be precluded by the use of a plurality of elements.

In various other embodiments, the MEMS yaw-rate sensor comprises a second magnetic-field-generating element and a second magnet-sensitive element, of which one is arranged on the main body or the first primary mass and one is arranged on the first secondary mass, wherein the second magnet-sensitive element is configured for determining the secondary movement of the first secondary mass relative to the first primary mass or relative to the main body. The measurement principle described above can be applied in this case. In particular, the second magnet-sensitive element can measure changes in the field strength and/or the field direction of the field generated by the second magnetic-field-generating element at the position of said second magnet-sensitive element and draw conclusions therefrom about the relative position of the first secondary mass with respect to the first primary mass or about the relative position of the first secondary mass with respect to the main body and thus about the secondary movement.

Furthermore, further magnetic-field-generating elements and further magnet-sensitive elements can be arranged on the main body, the first primary mass and the first secondary mass, by means of which the position of the secondary mass relative to the primary mass or relative to the main body is determined in order to be able to preclude ambiguities in the measurement results.

Embodiments of the invention thus make it possible to replace large-area electrodes which are required in capacitive sensors for detecting a deflection of a mass structure, in particular in a z-direction. Magnet-sensitive elements and magnetic-field-generating elements are now used instead, which have a significantly smaller spatial extent and thus allow further miniaturization of the MEMS yaw-rate sensor. The measurement with the aid of the magnetic-field-generating elements and the magnet-sensitive elements makes it possible, moreover, also to eliminate the further disadvantages described above in respect of the capacitive sensors, for example, interference influences of parasitic capacitances.

The magnetic-field-generating elements can comprise magnetic thin-film structures, in particular. Furthermore, the magnetic-field-generating elements can comprise magnetic dipole structures for magnetic field generation. The magnetic dipole structures can be arranged parallel or perpendicularly to the thin-film structures.

Alternatively, the magnetic-field-generating elements can comprise magnetic thick-film structures. Furthermore, the magnetic-field-generating elements can comprise magnetic dipole structures for magnetic field generation. The magnetic dipole structures can be arranged parallel or perpendicularly to the thick-film structures.

The magnet-sensitive elements can be in particular magnetoresistive XMR structures, e.g., AMR elements (AMR=anisotropic magnetoresistive), GMR elements (GMR=giant magnetoresistive) or TMR elements (TMR=tunneling magnetoresistive).

In embodiments of the yaw-rate sensor described here, a primary movement and a secondary movement are decoupled from one another by virtue of these movements being performed by a primary mass and a secondary mass, respectively. The measurement accuracy can be increased as a result. Disturbances in the primary movement, for example, as a result of linear accelerations or vibrations of the sensor, also influence the secondary movement. The influence of such disturbances can be reduced by the measurement of both movements independently of one another. This can be achieved by means of a suitable dimensioning of the springs. The MEMS yaw-rate sensor can be designed, for example, in such a way that the first primary mass only has degrees of freedom in one spatial direction and the first secondary mass can be deflected in two spatial directions, wherein the two spatial directions are the direction of the primary oscillation and the direction of the secondary oscillation which is brought about by the Coriolis force.

In further embodiments, both the primary movement and the secondary movement are measured with the aid of magnetic-field-generating elements and magnet-sensitive elements arranged on the main body, the first primary mass and the first secondary mass, wherein the magnet-sensitive elements can each measure changes in the field direction and/or the field strength of the fields generated by the magnetic-field-generating elements.

Furthermore, the yaw-rate sensor can comprise a second primary mass, which is configured to perform a primary oscillation relative to the main body, and a second secondary mass, which is connected to the second primary mass via a further suspension in such a way that the primary oscillation of the second primary mass excites a primary movement of the second secondary mass, and a secondary movement of the second secondary mass relative to the second primary mass is permitted.

In this case, the first primary mass and the second primary mass can be excited to perform oscillations which are phase-shifted by 180° with respect to one another. Disturbances, for example, accelerations, can be compensated for in this way.

In various further embodiments the sensor can furthermore comprise a third magnetic-field-generating element and a third magnet-sensitive element, of which one is arranged on the main body and one is arranged on the second primary mass, wherein the third magnet-sensitive element is configured for determining the primary movement of the primary mass relative to the main body. The sensor can furthermore comprise a fourth magnetic-field-generating element and a fourth magnet-sensitive element, of which one is arranged on the main body or the second primary mass and one is arranged on the second secondary mass, wherein the fourth magnet-sensitive element is configured for determining the secondary movement of the second secondary mass relative to the second primary mass or the main body.

The primary movement of the second primary mass and the secondary movement of the second secondary mass can thus likewise be measured with the aid of magnet-sensitive elements and magnetic-field-generating elements. The measurement accuracy of the sensor overall can be increased by the use of a second primary mass and a second secondary mass. In addition, disturbances can be compensated for in this way.

The second primary mass can be designed to perform a primary oscillation relative to the main body which is in antiphase with respect to the primary oscillation of the first primary mass. In particular, the first and second primary masses can be excited in antiphase with respect to one another. As a result of the in-antiphase excitation of the two primary masses, the sensor becomes less susceptible to disturbances.

The first primary mass and the second primary mass can be connected to one another via coupling springs. The first secondary mass and the second secondary mass can be connected to one another via coupling springs. The use of coupling springs can enable the in-antiphase oscillations to be better synchronized with one another and the measurement accuracy to be increased as a result.

The first primary mass can be a torsional oscillator, wherein the primary movement of the first primary mass is a torsional oscillation.

The primary movement of the first secondary mass can take place in the same direction as the primary movement of the first primary mass. Alternatively, the primary movement of the first secondary mass can take place perpendicularly to the primary movement of the first primary mass. A corresponding choice of the directions of the primary movement and of the secondary movement makes it possible to define the axis about which the sensor can be rotated and can measure the corresponding yaw rate. In this case, the sensor can always be designed to determine a yaw rate about an axis which is perpendicular to the direction of the primary movement of the secondary mass and perpendicular to the direction of the secondary movement of the secondary mass.

The first magnet-sensitive element and/or the second magnet-sensitive element can be arranged outside a plane in which the first primary mass extends in a non-deflected state. In particular, the first and/or the second magnet-sensitive element can be secured in a cover arranged above the first primary mass. Accordingly, the magnet-sensitive elements can be arranged above the first primary mass. In particular, the magnet-sensitive elements can be arranged in such a way that they are situated directly above the magnetic-field-generating elements in the non-deflected state of the first primary mass. This arrangement enables a particularly high sensitivity for movements of the primary mass in a direction in which the magnet-sensitive elements and the magnetic-field-generating elements are moved toward one another. This direction can be the z-direction.

Furthermore, the third magnet-sensitive element and/or the fourth magnet-sensitive element can be arranged outside a plane in which the first secondary mass extends in a non-deflected state. In particular, the third and/or the fourth magnet-sensitive element can be secured in the cover arranged above the first secondary mass. Accordingly, the magnet-sensitive elements can be arranged above the first secondary mass. In particular, the magnet-sensitive elements can be arranged in such a way that they are situated directly above the magnetic-field-generating elements in the non-deflected state of the first secondary mass. This arrangement enables a particularly high sensitivity for movements of the secondary mass in a direction in which the magnet-sensitive elements and the magnetic-field-generating elements are moved toward one another. This direction can be the z-direction.

The main body can comprise a cover and a substrate, wherein the first primary mass and the first secondary mass are encapsulated between the cover and the substrate. At least one magnet-sensitive element can be arranged at an inner side of the cover. By way of example, the first magnet-sensitive element and/or the second magnet-sensitive element and/or the third magnet-sensitive element and/or the fourth magnet-sensitive element can be arranged at an inner side of the cover.

The sensor can comprise further magnet-sensitive elements and magnetic-field-generating elements, wherein the MEMS yaw-rate sensor enables a measurement of yaw rates about a plurality of axes. In particular, the sensor can be configured for measuring yaw rates about each of the three spatial axes. In this case, the sensor can measure, for example, the movement of a secondary mass in each of the three spatial directions.

### BRIEF DESCRIPTION OF THE DRAWINGS

The present invention is described in greater detail below with reference to the figures.

FIG. 1 shows a MEMS yaw-rate sensor in accordance with a first exemplary embodiment.

FIG. 2 shows a MEMS yaw-rate sensor in accordance with a second exemplary embodiment.

FIG. 3 shows a MEMS yaw-rate sensor in accordance with a third exemplary embodiment.

FIG. 4 shows a MEMS yaw-rate sensor in accordance with a fourth exemplary embodiment.

FIG. 5 shows a MEMS yaw-rate sensor in accordance with a fifth exemplary embodiment.

FIG. 6 shows a MEMS yaw-rate sensor in accordance with a sixth exemplary embodiment.

FIG. 7 shows a MEMS yaw-rate sensor in accordance with a seventh exemplary embodiment.

FIG. 8 shows a MEMS yaw-rate sensor in accordance with an eighth exemplary embodiment.

FIGS. 9A, 9B and 9C show a MEMS yaw-rate sensor in accordance with a ninth exemplary embodiment.

FIG. 10 shows a MEMS yaw-rate sensor in accordance with a tenth exemplary embodiment.

FIG. 11 shows a cross section through a sensor.

### DETAILED DESCRIPTION OF ILLUSTRATIVE EMBODIMENTS

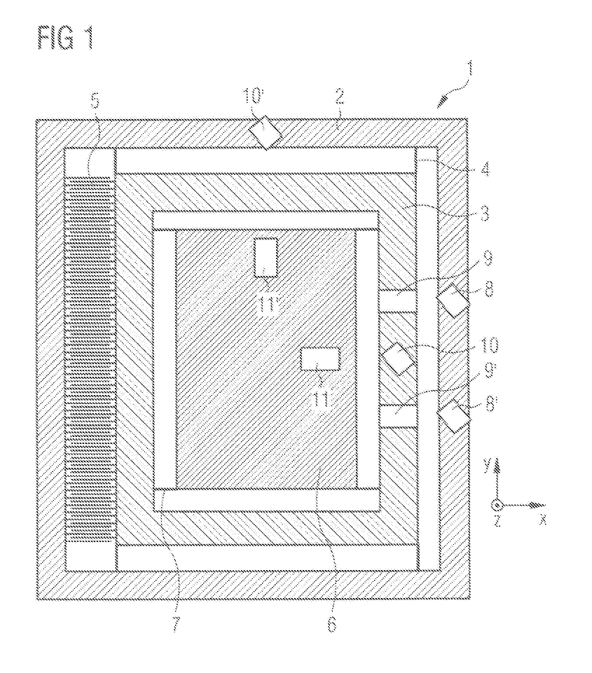

FIG. 1 shows a MEMS yaw-rate sensor 1. Hereinafter, direction indications are given with reference to the Cartesian coordinate system depicted in FIG. 1 and the further figures. The MEMS yaw-rate sensor 1 shown in FIG. 1 is designed for measuring a yaw rate about the z-axis.

The MEMS yaw-rate sensor 1 comprises a main body 2. The term main body 2 denotes a body which is not caused to perform oscillations. The main body 2 comprises a substrate and a cover (not shown in FIG. 1).

Furthermore, the MEMS yaw-rate sensor 1 comprises a first primary mass 3. The latter is connected to the main body 2 via primary springs 4. In particular, the first primary mass 3 is connected to the main body 2 via four primary springs 4, which are respectively arranged at a corner of the first primary mass 3. The primary springs 4 have an areal extent in the z-direction and in the y-direction. The primary springs 4 have a significantly smaller extent in the x-direction than in the y- and z-directions. Accordingly, the primary springs 4 preferably allow a movement of the first primary mass 3 relative to the main body 2 in the x-direction. In the y-direction and in the z-direction, by contrast, the primary springs 4 are rigid and permit no significant movement of the first primary mass 3 relative to the main body 2 in the y-direction and in the z-direction.

Furthermore, a drive element 5 is arranged between the main body 2 and the first primary mass 3, which drive element can excite the first primary mass 3 to perform a primary movement. The drive element 5 is a capacitor. The capacitor comprises mutually overlapping fingers which are formed alternately at the main body 2 and also at the first primary mass 3 and which each comprise excitation electrodes. If an AC voltage is then applied to the excitation electrodes, the first primary mass 3 is excited to perform a primary movement. The primary movement is an oscillation in the x-direction.

Furthermore, the MEMS yaw-rate sensor 1 comprises a first secondary mass 6. The first secondary mass 6 is connected to the first primary mass 3 via a suspension 7. The suspension 7 comprises secondary springs having an areal extent in the x-direction and in the z-direction. The secondary springs have a smaller extent in the y-direction than in the x-direction and in the z-direction. Accordingly, the suspension 7 is configured in such a way that the first secondary mass 6 can move in the y-direction relative to the first primary mass 3 and that the first secondary mass 6 cannot move significantly relative to the first primary mass 3 in the x-direction and in the z-direction.

The suspension 7 is configured in such a way that the primary movement of the first primary mass 3 relative to the main body 2 is transformed into a primary movement of the first secondary mass 6 relative to the main body 2. The primary movement of the first secondary mass 6 is likewise an oscillation in the x-direction relative to the main body 2.

In addition, the suspension 7 allows a secondary movement of the first secondary mass 6 relative to the first primary mass 3. The secondary movement is an oscillation in the y-direction relative to the first primary mass 3. If the MEMS yaw-rate sensor 1 is then rotated about the z-axis and furthermore if the first primary mass 3 is excited to perform a primary movement, i.e., to perform oscillations in the x-direction relative to the main body 2, the first secondary mass 6 experiences a Coriolis force which excites the first secondary mass 6 to perform oscillations in the y-direction. The measurement principle of the MEMS yaw-rate sensor 1 is based on measuring this secondary movement of the first secondary mass 6 in order to determine the yaw rate about the z-axis therefrom.

In the case of the MEMS yaw-rate sensor 1, the primary movement of the first primary mass 3 and the secondary movement of the first secondary mass 6 are measured independently of one another. For measuring the primary movement of the first primary mass 3 and the secondary movement of the first secondary mass 6, the MEMS yaw-rate sensor 1 uses magnetic-field-generating elements and magnet-sensitive elements.

The magnetic-field-generating elements each generate a magnetic field, the field strength and field direction of which are known accurately. The magnetic-field-generating elements can be magnetic dipole structures.

For measuring the fields generated by the magnetic-field-generating elements, the MEMS yaw-rate sensor 1 comprises the magnet-sensitive elements. The magnet-sensitive elements are magnetoresistive XMR structures. The magnet-sensitive elements make it possible to detect the distance with respect to a magnetic-field-generating element. On the basis of the measurement values of the magnet-sensitive elements, it is also possible to determine the position of a magnet-sensitive element relative to a magnetic-field-generating element.

In particular, the MEMS yaw-rate sensor 1 comprises a first magnet-sensitive element 8, which is arranged on the main body 2. Furthermore, a first magnetic-field-generating element 9 is arranged on the first primary mass 3. If the first primary mass 3 then performs a primary movement relative to the main body 2, the first magnet-sensitive element 8 can ascertain a change in the field direction and/or the field strength of the field generated by the first magnetic-field-generating element 9. The primary movement can be measured therefrom. In order to increase the accuracy further, the MEMS yaw-rate sensor 1 comprises a further first magnet-sensitive element 8′ on the main body 2 and a further first magnetic-field-generating element 9′ on the first primary mass 3. In this case, the term “first” elements denote the elements which enable the primary movement to be measured. Ambiguities in the measurement results can be precluded by the use of a plurality of first magnet-sensitive elements 8, 8′ on the main body and a plurality of magnetic-field-generating elements 9, 9′ on the first primary mass.

The secondary movement of the first secondary mass 6 is measured independently of the measurement of the primary movement of the first primary mass 3. The measurement of the secondary movement is also based on a magnetic principle in which a magnet-sensitive element 10 measures changes in field strength and/or field direction of a field generated by a magnetic-field-generating element 11.

To that end, a second magnetic-field-generating element 11 is arranged on the first secondary mass 6. A second magnet-sensitive element 10 is arranged on the first primary mass 3. If the first secondary mass 6 performs the secondary movement relative to the first primary mass 3, i.e., an oscillation in the y-direction, the second magnetic-field-generating element 11 is moved relative to the second magnet-sensitive element 10. The second magnet-sensitive element 10 identifies changes in the field strength and/or the direction of the magnetic field generated by the second magnetic-field-generating element 11 and can determine therefrom the secondary movement of the first secondary mass 6 relative to the first primary mass 3. In particular, the second magnet-sensitive element 10 can determine from changes in the field direction the angle by which the second magnetic-field-generating element 11 was moved from its initial position.

Furthermore, a further second magnetic-field-generating element 10′ is arranged on the first secondary mass 6 and a further second magnet-sensitive element if is arranged on the main body 2, which elements can determine a relative movement of the first secondary mass 6 with respect to the main body 2. In particular, the distance between the first secondary mass 6 and the main body 2 in the y-direction can be determined with the aid of the further second magnet-sensitive element 10′ and the further second magnetic-field-generating element 11′.

The secondary movement of the first secondary mass 6 can be measured from the measurement values determined by the magnetic-sensitive elements 10, 10′. In particular, the frequency of the secondary movement can be determined, which makes it possible to determine the yaw rate of the MEMS yaw-rate sensor 1 about the z-axis. Furthermore, the primary movement of the first primary mass 3 is measured in order to identify and thus be able to take account of disturbances in the primary movement that could influence the secondary movement and thus lead to measurement inaccuracies.

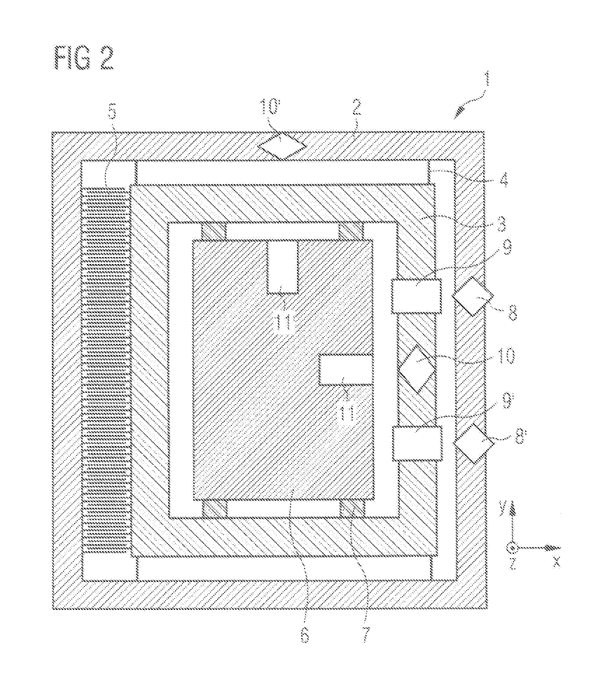

FIG. 2 shows a second exemplary embodiment of the MEMS yaw-rate sensor 1. The MEMS yaw-rate sensor 1 in accordance with the second exemplary embodiment is designed for determining a yaw rate about the y-axis.

The second exemplary embodiment differs from the first exemplary embodiment in the configuration of the secondary springs of the suspension 7. The secondary springs allow a movement of the first secondary mass 6 relative to the first primary mass 3 in the z-direction. They are embodied in a planar fashion in the x-direction and in the y-direction and have a significantly smaller extent in the z-direction. Accordingly, the first secondary mass 6 in accordance with the second exemplary embodiment can perform an oscillation in the z-direction as secondary movement. It is excited to perform this secondary movement by the Coriolis force if the MEMS yaw-rate sensor 1 rotates about the y-axis and the first primary mass 3 performs an oscillation in the x-direction which is transmitted to the first secondary mass 6.

Both in the exemplary embodiment shown in FIG. 1 and in the exemplary embodiment shown in FIG. 2, at least some of the magnetic-sensitive elements 8, 8′, 10, 10′ in an alternative configuration can also be arranged on the cover. Accordingly, the magnetic-sensitive elements 8, 8′, 10, 10′ can be arranged in a plane above a plane in which the magnetic-field-generating elements 9, 9′, ii, ii′ are situated if the first primary mass and the first secondary mass are situated in their respective initial position, i.e., if they are not performing a primary and/or secondary movement.

The magnetic-sensitive elements 8, 8′, 10, 10′ can be situated outside a plane in which the first primary mass 3 and the first secondary mass 6 extend. The first magnet-sensitive element 8 can be arranged at the cover in such a way that it is situated directly above the first magnetic-field-generating element 9 if the first primary mass 3 is situated in its initial position. The same applies to the further first magnet-sensitive element 8′ and the further first magnetic-field-generating element 9′. Furthermore, the second magnet-sensitive element 10 can be arranged at the cover in such a way that it is situated directly above the second magnetic-field-generating element 11 if the first secondary mass 6 is situated in its initial position. The same applies to the further second magnet-sensitive element 10′ and the further second magnetic-field-generating element 11′.

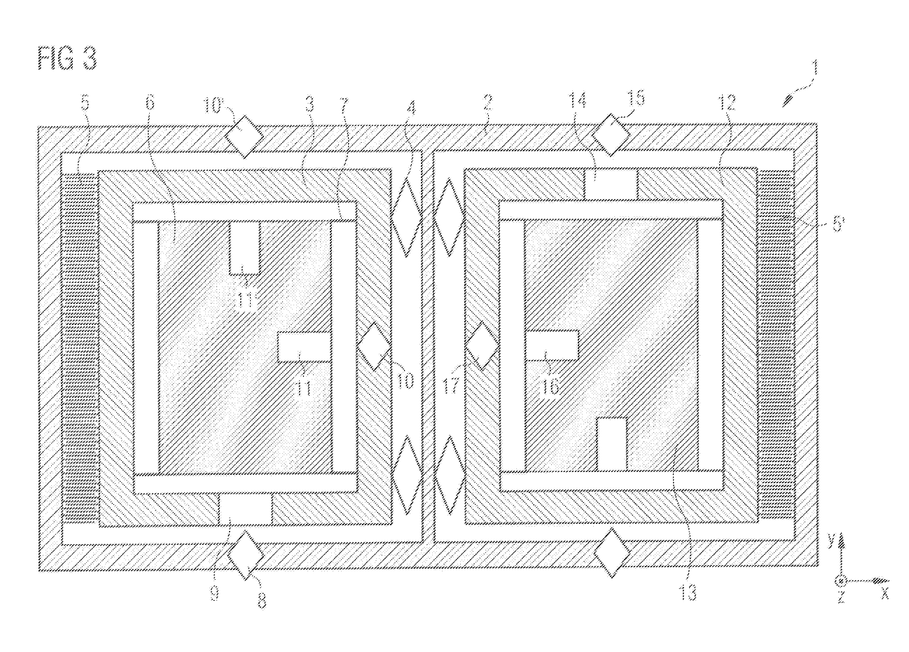

FIG. 3 shows a third exemplary embodiment of the MEMS yaw-rate sensor 1. The MEMS yaw-rate sensor 1 is configured for detecting a yaw rate about the z-axis.

In accordance with the third exemplary embodiment, the sensor 1 comprises a second primary mass 12 and a second secondary mass 13. The second primary mass 12 can be excited to perform a primary movement via a further drive element 5′. The primary movements of the first primary mass 3 and of the second primary mass 12 are in each case oscillations in the same direction, here in the x-direction. The second primary mass 12 can be excited in such a way that the primary movement of the second primary mass 12 proceeds in antiphase with respect to the primary movement of the first primary mass 3. In this case, the dimensioning of the springs 4 supports the in-antiphase movement.

For detecting the primary movement of the first and second primary masses 3, 12 and also the secondary movement of the first and second secondary masses 6, 13, provision is made of magnetic-sensitive elements 8, 10, 10′, 15, 17 and magnetic-field-generating elements 9, 11, 11′, 14, 16.

In particular, provision is made of magnetic-field-generating elements 9, 14 on the two primary masses 3, 12 and magnetic-sensitive elements 8, 15 on the main body 2 for detecting the two primary movements relative to the main body 2. By way of example, a third magnetic-field-generating element 14 is provided on the second primary mass 12 and a third magnet-sensitive element 15 is provided on the main body 2.

Furthermore, magnetic-field-generating elements 11, 11′, 16 are arranged on the secondary masses 6, 13. Furthermore, magnetic-sensitive elements 10, 10′ are arranged on the primary masses 3, 12 and the main body 2, which identify the relative movement of the secondary masses 6, 13 on the basis of the change in position of the magnetic-field-generating elements 11, 11′ on the secondary masses 6, 13. By way of example, a fourth magnetic-field-generating element 16 is arranged on the second secondary mass 13 and a fourth magnet-sensitive element 17 is arranged on the second primary mass 12. The further elements make it possible to detect tiltings and/or rotations which could be brought about, for example, by external disturbances or an inaccurate production process. In addition, the accuracy of the detection of a deflection and/or the detection of a position in one or more of the three spatial directions could be increased by means of the further elements.

In an alternative configuration of the third exemplary embodiment, at least some of the magnetic-sensitive elements 8, 10, 10′, 15, 17 can be arranged at the cover in each case vertically above one of the magnetic-field-generating elements 9, 11, 11′, 14, 16.

The measurement accuracy of the MEMS yaw-rate sensor 1 can be increased by the use of the second primary mass 12 and the second secondary mass 13. In addition, the sensor 1 becomes less susceptible to disturbances. This can be further improved by the in-antiphase excitation of the two primary masses 3, 12.

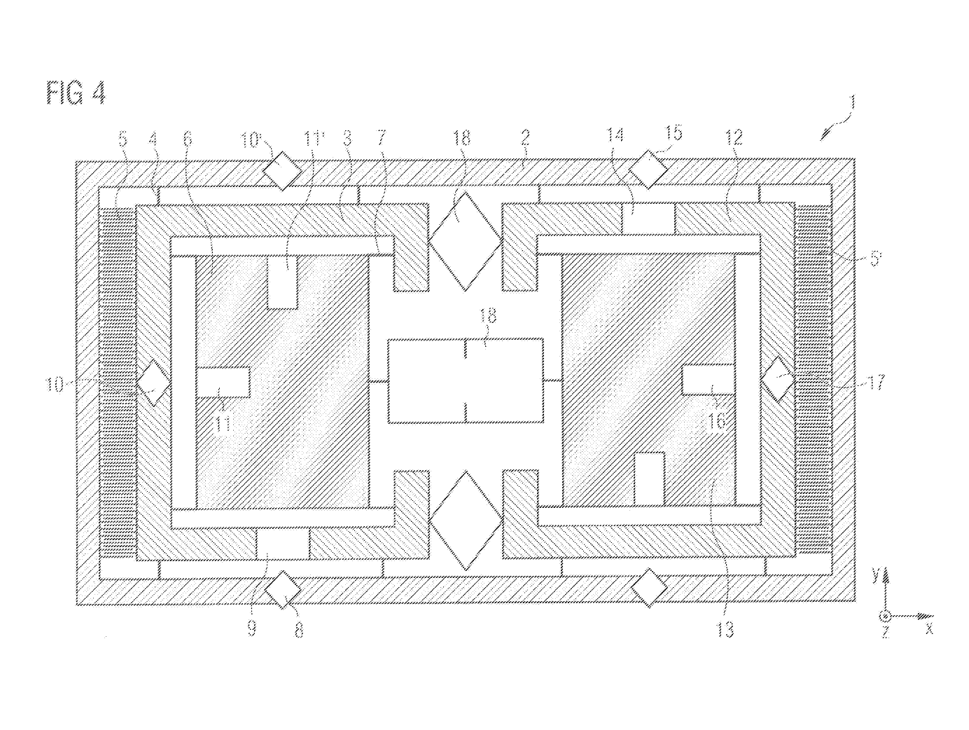

FIG. 4 shows a further exemplary embodiment of the MEMS yaw-rate sensor 1 in which the sensor 1 likewise comprises a second primary mass 12 and a second secondary mass 13. The MEMS yaw-rate sensor 1 shown in FIG. 4 is designed for determining a yaw rate about the z-axis. For detecting the primary movement of the first and second primary masses 3, 12 and also the secondary movement of the first and second secondary masses 6, 13, provision is made of magnetic-sensitive elements 8, 10, 10′, 15, 17 and magnetic-field-generating elements 9, ii, 11′, 14, 16.

In the fourth exemplary embodiment, the first primary mass 3 is connected to the second primary mass 12 via coupling springs 18. The coupling springs 18 allow a movement of the first primary mass 3 relative to the second primary mass 12 in the x-direction. Furthermore, the second secondary mass 13 is also connected to the first secondary mass 6 via coupling springs 18, which allow a movement of the first secondary mass 6 relative to the second secondary mass 13 in the x-direction.

The coupling springs 18 between the primary masses 3, 12 and the secondary masses 6, 13 make it possible to synchronize the in-antiphase oscillations of the first and second primary masses 3, 12 more accurately. The measurement accuracy can be increased in this way.

The secondary masses 6 and 13 can perform an oscillation in antiphase with respect to one another in the y-direction as well. The coupling spring 18 connecting the two secondary masses 6, 13 to one another should be configured in this case such that it permits the oscillation in antiphase with respect to one another in the y-direction.

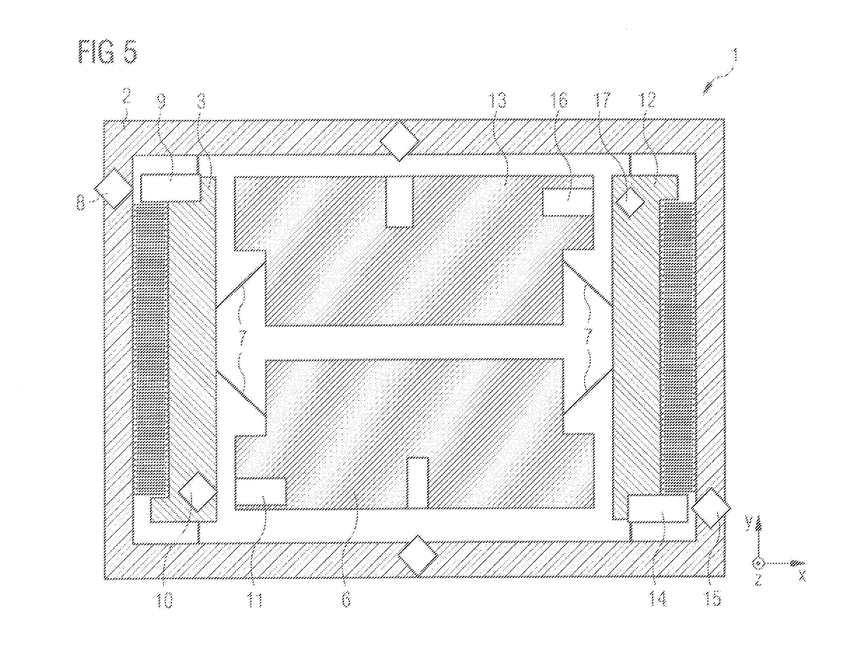

FIG. 5 shows a fifth exemplary embodiment of the MEMS yaw-rate sensor 1. In accordance with the fifth exemplary embodiment, too, the yaw-rate sensor 1 comprises a second primary mass 12 and a second secondary mass 13. For detecting the primary movement of the first and second primary masses 3, 12 and also the secondary movement of the first and second secondary masses 6, 13, provision is made of magnetic-sensitive elements 8, 10, 15, 17 and magnetic-field-generating elements 9, 11, 14, 16.

The first secondary mass 6 is connected both to the first primary mass 3 and to the second primary mass 12 via a suspension 7. The second secondary mass 13 is also connected both to the first primary mass 3 and to the second primary mass 12 via a suspension 7. The two suspensions 7 are configured here in each case in such a way that a primary movement of the primary masses 3, 12 in the x-direction is deflected into a primary movement of the secondary masses 6, 13 in the y-direction, that is to say in a direction which is perpendicular to the direction of the primary movement of the primary masses 3, 12. The first and second primary masses 3, 12 are preferably excited to perform in-antiphase oscillations in the x-direction. Consequently, the two secondary masses 6, 13 are excited to perform in-antiphase oscillations in the y-direction.

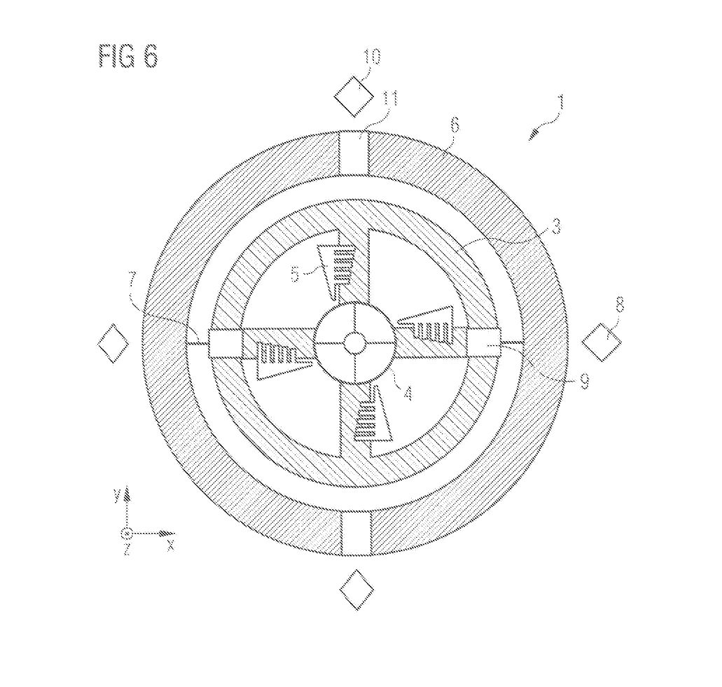

FIG. 6 shows a sixth exemplary embodiment of the MEMS yaw-rate sensor 1. In accordance with the sixth exemplary embodiment, the first primary mass 3 is a torsional oscillator. The latter is connected to the main body via a primary spring 4. The primary spring 4 is planar in the z-direction. The first primary mass 3 can be excited to perform a primary movement during which it performs a torsional oscillation about the z-axis. It accordingly oscillates in the x-y-plane.

The MEMS yaw-rate sensor 1 comprises a drive element 5, which can excite the first primary mass 3 to perform the primary movement. The drive element 5 comprises capacitors having mutually overlapping fingers which are formed alternately at the main body and at the first primary mass 3 and which each comprise excitation electrodes. If an AC voltage is then applied to the excitation electrodes, the primary mass is excited to perform the primary movement, i.e., a torsional oscillation in the x-y-plane.

The first primary mass 3 comprises four arms and a ring-shaped body, wherein the arms extend inward from the ring-shaped body. The arms are connected to the primary spring 4.

Furthermore, a ring-shaped first secondary mass 6 is provided, which is connected to the primary mass 3 via a suspension 7. The suspension 7 is secondary springs which are embodied in a planar fashion in the x-direction and in the y-direction and which have a smaller extent in the z-direction. They are designed for transmitting the primary movement, that is to say the torsional oscillation, to the first secondary mass 6. In addition, they allow a tilting of the first secondary mass 6 in the z-direction relative to the first primary mass 3. Accordingly, the first secondary mass 6 can perform an oscillation in the z-direction relative to the first primary mass 3 as secondary movement.

The sensor 1 is designed for measuring yaw rates about the y-axis. If the first primary mass 3 is excited to perform the above-described primary movement that is transmitted to the first secondary mass 6, and if the sensor 1 is rotated about the y-axis, the first secondary mass 6 is excited by the Coriolis force to perform a secondary movement, i.e., an oscillation in the z-direction.

The MEMS yaw-rate sensor 1 comprises corresponding magnetic-field-generating elements 9, ii and magnetic-sensitive elements 8, 10 which, as in the previous exemplary embodiments, make it possible to measure the primary movement of the first primary mass 3 and the secondary movement of the first secondary mass 6. The magnetic-sensitive elements 8, 10 are arranged on the main body. The magnetic-field-generating elements 9, ii are arranged on the first primary mass 3 and on the first secondary mass 6.

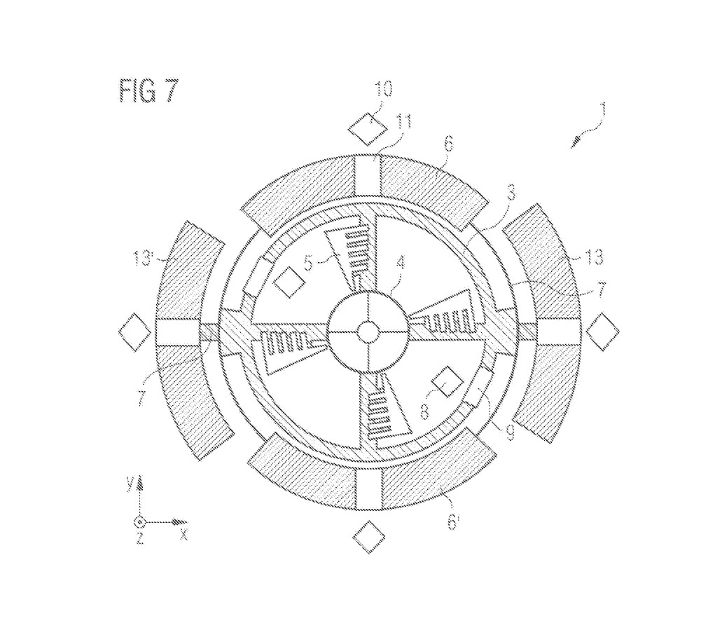

FIG. 7 shows a seventh exemplary embodiment of the MEMS yaw-rate sensor 1. Here, too, the first primary mass 3 is configured as a torsional oscillator.

The MEMS yaw-rate sensor 1 in accordance with the seventh exemplary embodiment differs from the sixth exemplary embodiment in that the MEMS yaw-rate sensor 1 comprises four secondary masses 6, 13, 6′, 13′, which are coupled to the first primary mass 3 in each case via a suspension 7. The suspension 7 has a significant extent only in the z-direction. In the other spatial directions, the suspension 7 is formed as a long, thin web. In this case, two secondary masses 6, 6′ are connected to the first primary mass 3 via the secondary springs in such a way that they can perform an oscillation in the z-direction relative to the first primary mass 3 as secondary movement. As in the sixth exemplary embodiment, a yaw rate about the y-axis can be determined by a measurement of said secondary movement.

Furthermore, the two further secondary masses 13, 13′ are connected to the first primary mass 3 via the secondary springs in such a way that they can perform an oscillation in the y-direction relative to the first primary mass 3 as secondary movement. A yaw rate about the x-axis can be determined by a measurement of said secondary movement. Accordingly, the MEMS yaw-rate sensor 1 in accordance with the seventh exemplary embodiment makes it possible to measure yaw rates about two axes.

In each case at least one magnetic-field-generating element 9, ii is arranged on each of the four secondary masses 6, 6′, 13, 13′ and on the first primary mass 3. Furthermore, magnetic-sensitive elements 8, 10 are arranged on the main body, which magnetic-sensitive elements measure the field direction and/or the field strength of the fields generated by the magnetic-field-generating elements 9, ii and determine therefrom the secondary movements and the primary movement.

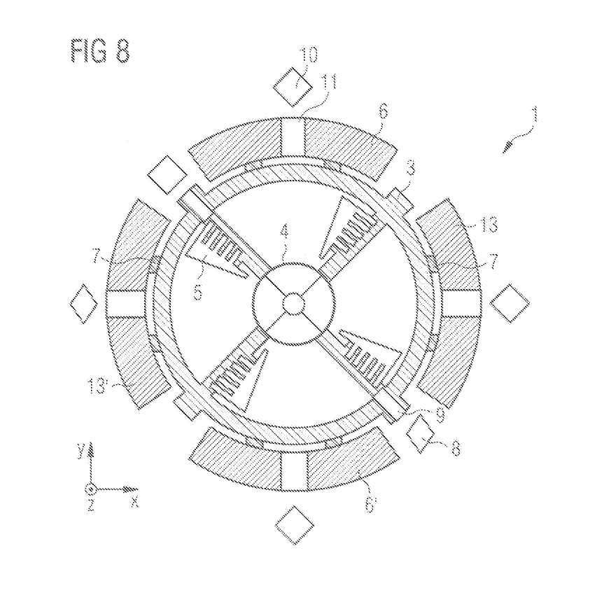

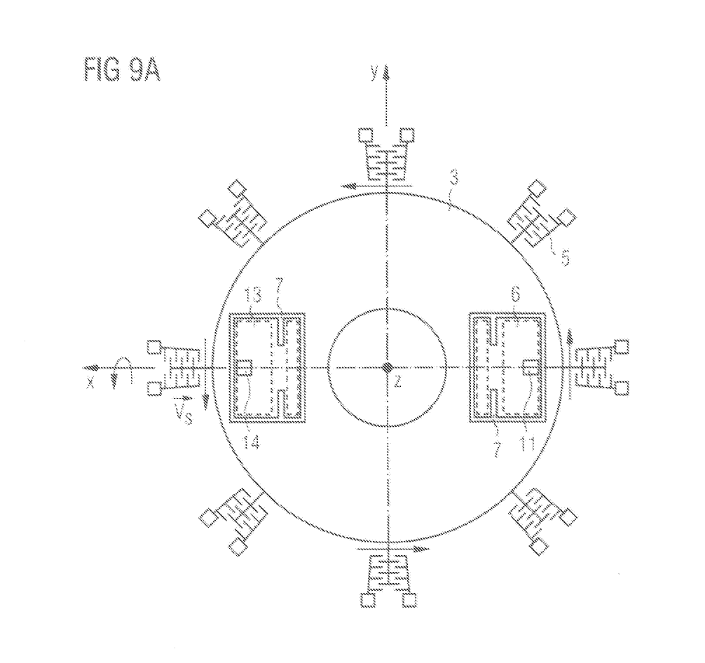

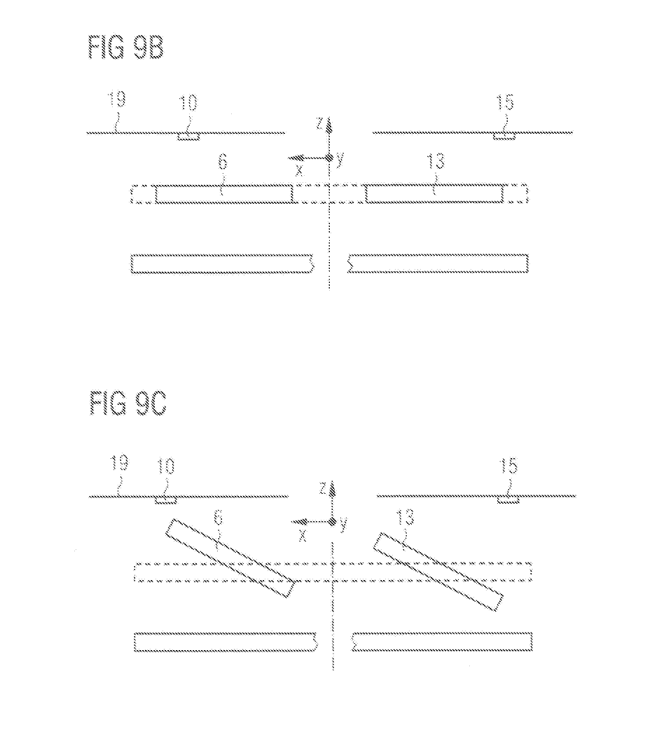

FIG. 8 shows an eighth exemplary embodiment of the sensor 1. In accordance with the eighth exemplary embodiment, the sensor 1 comprises four secondary masses 6, 6′, 13, 13′, which oscillate in antiphase in pairs and are suitable for detecting yaw rates about the x-axis and the y-axis. The suspension 7 is embodied here as spring beams, wherein the spring beams are deflectable by a force acting in the z-direction. With respect to forces in the x-direction or the y-direction, by contrast, the spring beams are stiff and act in a substantially stiff fashion.

FIGS. 9A, 9B and 9C show the yaw-rate sensor 1 in accordance with a ninth exemplary embodiment. FIG. 9A shows the sensor in a plan view. FIG. 9B and FIG. 9C each show a part of the sensor in each case in a cross section. FIG. 9A here shows the sensor in a non-deflected state. FIG. 9C shows the sensor in the deflected state.

The sensor 1 is a uniaxial rotational gyrostructure. The sensor 1 comprises a first primary mass 3 and secondary masses 6, 13 suspended movably with respect thereto. The first primary mass 3 can be excited by a drive element 5 to perform a primary movement which is a torsional oscillation in the x-y-plane. The suspension 7 of the secondary masses 6, 13 allows the latter to perform an oscillation in the z-direction as secondary movement. Yaw rates can be determined in this way.

Magnetic-sensitive elements 10, 15 are arranged in a cover 19 of the sensor. Magnetic-field-generating elements 11, 14 are arranged on the secondary masses 6, 13.

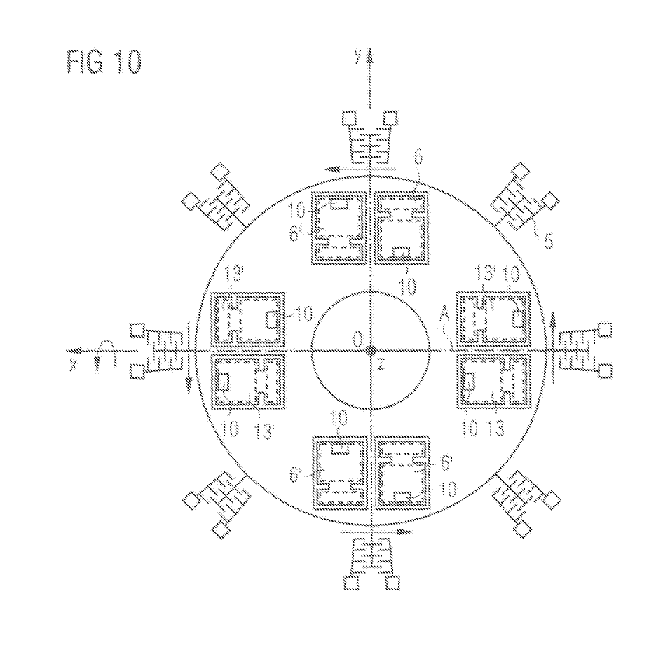

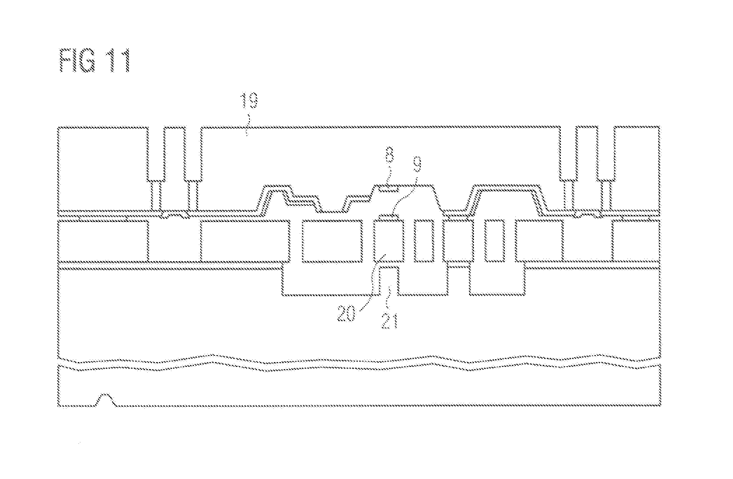

FIG. 10 shows a tenth exemplary embodiment, which differs from the ninth exemplary embodiment in that further secondary masses 6′, 13′ are provided. The secondary masses 6, 6′, 13, 13′ in this case are suspended in such a way that at least one secondary mass performs an oscillation in a first direction as secondary movement and at least one other secondary mass performs an oscillation in a second direction perpendicular thereto as secondary movement. In this way, it is possible to simultaneously determine yaw rates about a plurality of axes using the sensor 1. As in the ninth exemplary embodiment, magnetic-field-generating elements 11 and magnetic-sensitive elements 10 are provided on the secondary masses 6, 6′, 13, 13′ and respectively at the cover 19 of the sensor 1.

FIG. 11 shows a cross section through a sensor 1 in which a magnetic-field-generating element 9 is provided on a movable mass 20 and a magnet-sensitive element 8 is provided at an inner side of a cover 19. A stop 21 is configured to limit the movement of the movable mass 20. The movable mass 20 can be, for example, a primary mass or a secondary mass.

1-12. (canceled)

13. A MEMS yaw-rate sensor comprising:
a main body;
a first primary mass configured to perform a primary oscillation relative to the main body;
a first secondary mass connected to the first primary mass via a first suspension such that a primary movement of the first primary mass excites a primary movement of the first secondary mass and a secondary movement of the first secondary mass relative to the first primary mass is permitted;
a first magnetic-field-generating element and a first magnet-sensitive element, one being arranged on the main body and one being arranged on the first primary mass, wherein the first magnet-sensitive element is configured to determine the primary movement of the first primary mass relative to the main body; and
a second magnetic-field-generating element and a second magnet-sensitive element, one being arranged on the main body or the first primary mass and one being arranged on the first secondary mass, wherein the second magnet-sensitive element is configured to determine the secondary movement of the first secondary mass relative to the first primary mass or relative to the main body.

14. The MEMS yaw-rate sensor according to claim 13, further comprising:
a second primary mass configured to perform a primary oscillation relative to the main body;
a second secondary mass connected to the second primary mass via a second suspension such that the primary oscillation of the second primary mass excites a primary movement of the second secondary mass and a secondary movement of the second secondary mass relative to the second primary mass is permitted;
a third magnetic-field-generating element and a third magnet-sensitive element, one being arranged on the main body and one being arranged on the second primary mass, wherein the third magnet-sensitive element is configured to determine the primary movement of the second primary mass relative to the main body; and
a fourth magnetic-field-generating element and a fourth magnet-sensitive element, one being arranged on the main body or the second primary mass and one being arranged on the second secondary mass, wherein the fourth magnet-sensitive element is configured to determine the secondary movement of the second secondary mass relative to the second primary mass.

15. The MEMS yaw-rate sensor according to claim 14, wherein the second primary mass is designed to perform a primary oscillation relative to the main body which is in antiphase with respect to the primary oscillation of the first primary mass.

16. The MEMS yaw-rate sensor according to claim 14, wherein the first primary mass and the second primary mass are connected to one another via coupling springs.

17. The MEMS yaw-rate sensor according to claim 14, wherein the first secondary mass and the second secondary mass are connected to one another via coupling springs.

18. The MEMS yaw-rate sensor according to claim 13, wherein the first primary mass is a torsional oscillator, and wherein the primary movement of the first primary mass is a torsional oscillation.

19. The MEMS yaw-rate sensor according to claim 13, wherein the primary movement of the first secondary mass takes place in the same direction as the primary movement of the first primary mass.

20. The MEMS yaw-rate sensor according to claim 13, wherein the primary movement of the first secondary mass takes place perpendicularly to the primary movement of the first primary mass.

21. The MEMS yaw-rate sensor according to claim 13, wherein the first magnet-sensitive element and/or the second magnet-sensitive element are/is arranged outside a plane in which the first primary mass extends in a non-deflected state.

22. The MEMS yaw-rate sensor according to claim 14, wherein the third magnet-sensitive element and/or the fourth magnet-sensitive element are/is arranged outside a plane in which the first secondary mass extends in a non-deflected state.

23. The MEMS yaw-rate sensor according to claim 13,
wherein the main body comprises a cover and a substrate, wherein the first primary mass and the first secondary mass are encapsulated between the cover and the substrate, and
wherein at least one magnet-sensitive element is arranged at an inner side of the cover.

24. The MEMS yaw-rate sensor according to claim 13, further comprising further magnet-sensitive elements and magnetic-field-generating elements, wherein the MEMS yaw-rate sensor is configured to enable a measurement of yaw rates about a plurality of axes.
